(19) United States
(12) Patent Application Publication
(10) Pub. No.: US 2002/0006032 A1
(43) Pub. Date: Jan. 17, 2002

(54) Low-profile registered DIMM

(76) Inventor: Chris Karabatsos, Kingston, NY (US)

Correspondence Address: Mark P. White, Suite 103, 57 Bedford Street, Lexington, MA, 02420, US

(21) Appl. No.: 09/758,791

(22) Filed: Jan. 11, 2001

Related U.S. Application Data
(60) Provisional application No. 60/206,287, filed on May 23, 2000.

(51) Int. Cl. H05K 7/02

(52) U.S. Cl. 361/760

(57) ABSTRACT

A low profile, registered DIMM has a height of about 1.2 inches, and a width of about 5.25 inches. This reduced size is accomplished by arranging the SDRAMs into a left group and a right group within a single row, with a space between the groups into which all other major components are disposed. In addition, the pad extensions beyond the SDRAM pins are maintained at about 0.1 mm, the footprints of the pads to accept the SDRAMs are a minimum of 11.76 mm, as measured by the lengthwise distance from the first pad in a footprint to the pad furthest away, and the space between adjacent pads is between 0.127 mm and 0.750 mm.

This application claims priority based on Provisional Application No. 60/206,287, filed on May 23, 2000.

### BACKGROUND OF THE INVENTION

1. Field of the Invention

The present invention relates to a low-profile DIMM memory board for use in personal computers, and more specifically, to such a memory board providing a high density of memory chips in a board configuration approximately 1.2 inches in height.

2. Description Relative to the Prior Art

Modem computers have their random-access memory (RAM) configured as separate memory modules, formed of a plurality of individual memory PC boards, with memory chips mounted thereon. These memory modules include SIMMS (Single In-line Memory Modules), which were initially designed as 30 pin, 8 bit wide assemblies which mated with a suitable 30 pin female socket. Soon however increasing computer memory demands saw the introduction of a memory module extender which permitted single 30 pin SIMM sockets to receive a plurality of 30 pin SIMMs.

As memory requirements became more demanding, 64 bit Dual In-line Memory Modules, hereinafter referred to as DIMMs were designed and incorporated into personal computers, requiring 168 pin sockets.

The continuing development of new memory modules has highlighted the continuing increase in the amount of RAM needed in the modem computer, as programs running on these computers require more and more memory to operate. As an example, the newer versions of Microsoft's Windows® operating systems requires up to 128 Mbytes of RAM to operate efficiently.

Furthermore, the incorporation of multi-media functions into modern software means that computer memory must operate at higher and higher speeds. As a result, the computer industry is faced with every increasing pressures to produce memory modules including more and more memory, in smaller and smaller packages.

The standards for computer memories are currently maintained by The JEDEC® Solid State Technology Association, once known as the Joint Electron Device Engineering Council. JEDEC is the semiconductor engineering standardization body of the Electronic Industries Alliance (EIA), a trade association that represents all areas of the electronics industry. More information on this organization appears on its WEB site at http://wwwjedec.org.

JEDEC standards are currently used in conjunction with the following configurations of DIMMS:

a) MO160-B-72 Pin Dual-In-Line Memory Module (DIMM) Family with 1.27 mm Contact Centers.

b) MO167-C-128 Pin Dual-In-Line memory Module (DIMM) Family, 1.27 mm Lead Centers. MO172-D-112 & 200 Pin Dual-In-Line Memory Module (DIMM) Family, 1.27 mm Pitch.

c) MO177-A-200 Pin Small Outline Dual-In-Line Memory Module (DIMM) Family, 0.65 mm Pitch. MO179-A-278 Pin Dual-In-Line Memory module (DIMM) Family with 1.00 Lead Centers.

d) MO190-C-144 Pin Small Outline Dual-In-Line Memory Module (DIMM) Family 0.8 mm Lead Centers. Item

e) MO191-A-160 Pin Dual-In-Line Memory Module (DIMM) Family, 1.27 mm Lead Centers.

f) MO206-A-184 Pin DDR Dual-In-Line Memory Module (DIMM) Family, 1.27 mm Contact Centers.

g) MO214-A-144 Pin Micro Dual-In-Line Memory Module (DIMM), 0.50 mm Pitch.

h) MO224-A-200 Pin DDR Small Outline Dual-In-Line Memory Module (SODIMM) Family, 0.60 mm Contact Centers. Item 11.14-043.

i) MO227-A-232 Pin DDR SDRAM DIMM Family, 1.00 mm Pitch.

All of the above DIMMs, when using registers and/or PLLs, have profiles of 1.5 inches or greater. The unavailability of DIMMs with lower profiles has had a serious, negative effect on many computer designs.

As an example, a common system standard for servers has a rack-mounted enclosure, with an external cabinet height of 1.75 inches. Manufacturers of these systems includes Network Engines, Inc., of Canton, Mass., and their “Roadster LX” is an representative example of such systems. This configuration became an industry standard prior to the appearance of the DIMM as a memory standard.

In order to fit the currently-available DIMMs into these cabinets, the manufacturers have had to take extraordinary steps, including slanting the DIMM sockets at 22½ degrees. Slanting the sockets in this way causes maintenance and accessability problems, and takes up an inordinate amount of space within the cabinet.

DIMMS are currently generally populated with SDRAM chips of a configuration as shown in FIG. 6. This SDRAM has 66 pin, with a width d4, of 11.76 mm from end of pin to end of pin, as shown, and a body width d5 of 10.16 mm. FIG. 4A shows the top side of a DIMM module manufactured by Intel®. The specifications for this module are shown in the table provided as Appendix A. By referring to FIG. 4A, it is seen that the top face of the module is populated not only by SDRAMs 2, but also by some additional chips 5, mounted sideways below the SDRAMs on the face. Similarly, the back face of the same module, as shown in FIG. 4B, could contains additional chips, although these are not shown in the figure. The non-SDRAM chips on both faces of this prior art DIMM require that the multilayer board be at least 1.5 inches in height. FIG. 2A shows the front side of this Intel DIMM, while FIG. 2B shows the back side. The height A of this DIMM is 1.7 inches.

The specifications for a different prior art DIMM, manufactured by IBM®, appear attached hereto as Appendix B. Referring now to Appendix B, the height of all of the DIMMs in this family 1.7 inches.

A review of the prior art of all the major manufacturers fails to show any DIMMs with an overall height of less than 1.5 inches, despite the obvious need expresses by the industry.

The current invention, however, provides a DIMM memory module in a 168, 184, and 200-pin , low profile configuration, with a height of only 1.2 inches, therefore solving the height problem which the industry has long sought to remedy.

### SUMMARY OF THE INVENTION

It is a general object of the present invention to provide a low profile DIMM with a height of between 1.125 and 1.250 inches, while still maintaining the memory capacity, speed, and performance of the higher-profile DIMMs. It is a specific object of this invention to provide techniques allowing the reduction in profile of memory boards, and of similar electronic boards.

In accordance with one aspect of the invention, a low-profile DIMM includes two or more printed circuit boards, bonded together to form a single multilayer board, having two sides, said board having a height of approximately 1.2 inches, and a width of approximately 5.25 inches. The invention includes a number of SDRAM chips, and a number of other components, so that, on each side of the multilayer board the SDRAM chips are arranged in a single row separated into a left group and a right group with a space between the groups, and where all the other components of significant size are disposed in the space between the groups.

In accordance with a second aspect of the invention, the left group consists of 5 SDRAM chips, and the right group contains 4 SDRAM chips.

In accordance with a third aspect of the invention, , the left group consists of 4 SDRAM chips, and the right group contains 5 SDRAM chips.

In accordance with a fourth aspect of the invention, each of the SDRAM chips has a number of pins, and the DIMM further includes a number of SDRAM mounting areas, each having two rows, each row having a multiplicity of pads, each pad electrically connected to one of the pins of a corresponding SDRAM chip, and each pad having an extension beyond the corresponding pin of about 0.1 mm. The maximum distance allowed between the end of the pad in one row to the end of the corresponding pad in the other row in a mounting area is about 11.76 mm.

In accordance with a fifth aspect of the invention, the space between adjacent pads is between 0.127 mm and 0.750 mm.

In accordance with a sixth aspect of the invention, the DIMM includes a Register chip, where the Register chip has a major axis, the DIMM has a major axis, and each SDRAM chip has a body and a major axis, and where the register chip is oriented with its major axis parallel to the major axis of the DIMM, and each SDRAM chip has it major axis oriented perpendicular to the major axis of the DIMM.

In accordance with a seventh aspect of the invention, the additional components include a number of decoupling capacitors, where each decoupling capacitor is mounted to the DIMM in proximity to the SDRAM pin closest to an end of the SDRAM, and less than or equal to 0.7 mm from the body of the SDRAM.

In accordance with a final aspect of the invention, the low-profile DIMM, includes two or more printed circuit boards, bonded together to form a single multilayer board, having two sides, the board having a height of approximately 1.2 inches, and a width of approximately 5.25 inches. On each side of the board is mounted a number of SDRAM chips, each having a major axis, arranged in a single row, and all save one having its major axis perpendicular to the major axis of the multilayer board. The row has a left group comprising 4 SDRAMS, and a right group of 4 SDRAMS with a space between the groups. The remaining SDRAM is mounted in the space between the groups, its major axis perpendicular to the major axis of the DIMM. The board also contains a number of other components, mounted on both sides of the multilayer board, and all these other components of significant size are mounted in the space between the left and right groups.

### BRIEF DESCRIPTION OF THE DRAWINGS

These, and further features of the invention, may be better understood with reference to the accompanying specification and drawings depicting the preferred embodiment, in which:

FIG. 1A depicts a front elevation view the front face of the DIMM with components mounted, in the 5-4 configuration.

FIG. 1B depicts a front elevation view the front face of the DIMM with components mounted, in the 4-5 configuration.

FIG. 1A depicts a front elevation view the front face of the DIMM with components mounted, in the 4-4 configuration.

FIG. 2A depicts the front elevation view of a two-sided DIMM memory board of the prior art, without components mounted.

FIG. 2B depicts a back side elevation view of a two-sided DIMM memory of the prior art, without components mounted.

FIG. 3 depicts top face of the printed circuit features of the current DIMM memory board without the components mounted.

FIG. 4A depicts a prior art DIMM configuration, top side.

FIG. 4B depicts a prior art DIMM configuration, bottom side.

FIG. 5A depicts a cross-sectional view of two adjacent SDRAMs mounted on the PC board.

FIG. 5B depicts a close-up view of the pin and pad on the left-hand side of FIG. 5A.

FIG. 6 depicts a exemplary SDRAM chip, showing pin spacing.

### DEFINITIONS

In the following disclosure the definitions below will be used:

a) PC board: the multi-layer board on which the SDRAM memory chips, register chips, and other components are mounted.

b) Module, or Memory Module: the PC board with the components mounted thereon.

c) Memory Chips: this term is used interchangeably with, or in combination with, the term SDRAM, which refers to a particular memory chip.

### DESCRIPTION OF THE PREFERRED EMBODIMENTS

This embodiment of the current invention is a configuration of a DIMM memory module which has a high density of memory chips on both sides of the board, providing a high memory capacity, with a board dimension of approximately 1.2 inches in height, by a width of approximately 5.25 inches. Using the techniques and configurations described herein, the current invention provides memory capacity up to 1 GBytes, according to the current technology in memory chips.

The ability to configure the DIMM into a PC (printed circuit) board only 1.2 inches in height depends upon using several different techniques in combination.

First, the SDRAM memory chips are mounted in a single row with their major axis perpendicular to the major axis of the PC board. The row of SDRAMs is divided into a left half group and a right half group, with a space between them. The other major components, in this case semiconductor chips, are mounted in the space between the left half and right half groups. Thus, the limitation in height of the PC board becomes, in effect, the length of the SDRAM, with a margin above and below the SDRAM row for mounting, edge connector, etc.

A second technique for reducing the size of the module involves restricting the size of the pad upon which the SDRAMs are mounted, and restricting the space between adjacent pads.

### COMPONENT MOUNTING

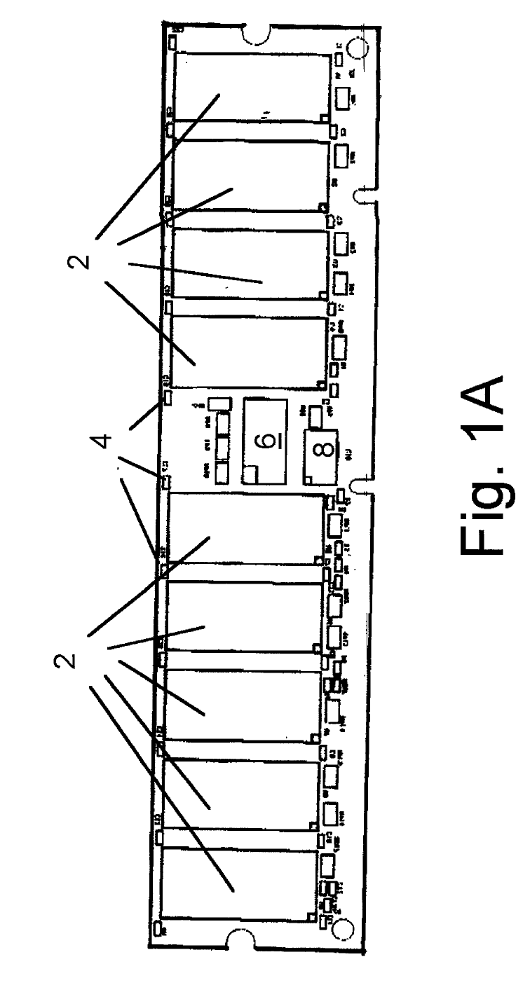

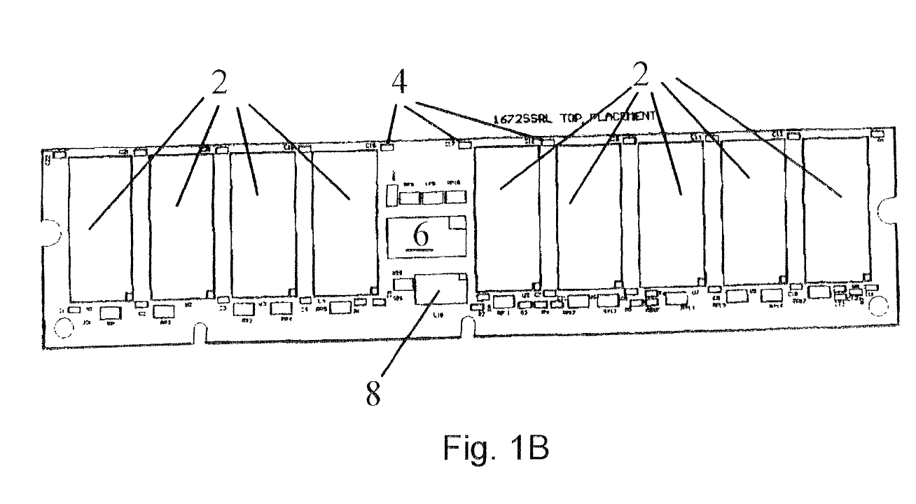

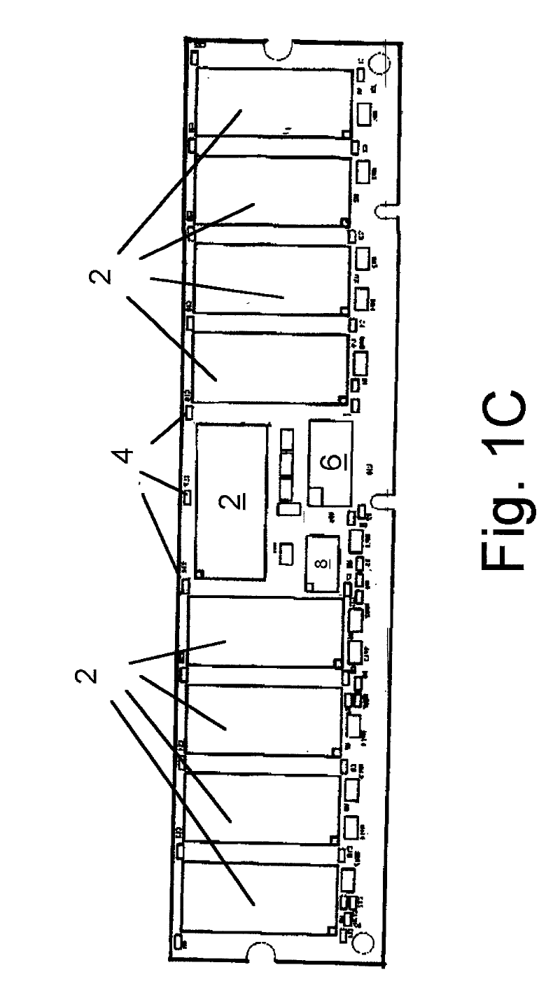

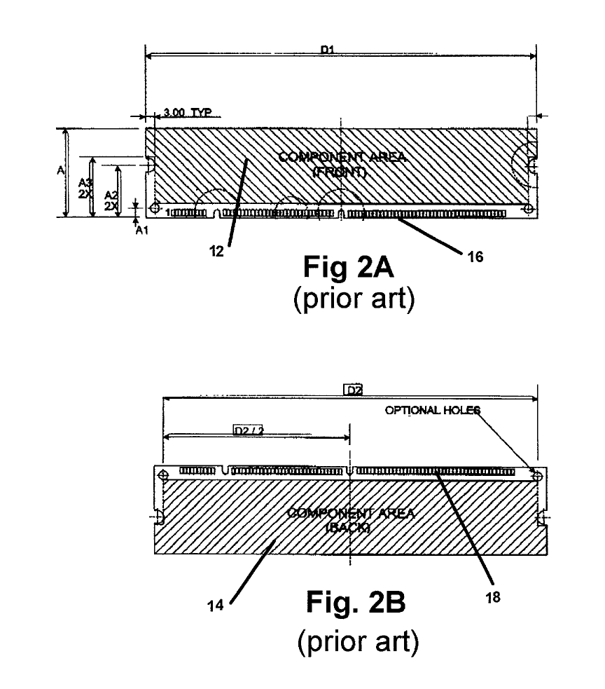

FIG. 1A depicts the front face of a two-sided DIMM memory board of the current invention without components mounted. Referring to this figure, the overall length D1 is 5.25 inches, while the overall height A is 1.2 inches. This height is significantly smaller than the JEDEC standard for this configuration, which is between 1.5 and 1.7 inches. FIG. 1A has 5 SDRAMs mounted to the left of the central gap, or space, and 4 SDRAMs to the right of the gap. The gap is seen as containing the Register chip 6, and the PLL (phase-locked loop) chip, 8. This configuration in referred to hereinafter as the 5-4 configuration.

FIG. 1B depicts a variation of this same configuration, with 4 SDRAMs mounted to the left of the gap, and 5 SDRAMs to the right. The configuration of FIG. 1B is referred to hereinafter as the 4-5 configuration.

FIG. 1C depicts a second variation, referred to as the 4-1-4 configuration. In this configuration, the gap contains an SDRAM, although rotated so that the major axis of the SDRAM is parallel to the major axis of the module, with the Register chip and PLL chip below the SDRAM in the central gap.

Regardless of which of these variations is used, it is still necessary to have 9 SDRAMs on either side of the module, in order to provide the required memory capacity for the current application. The overall module size is the same for all three variations described above.

Still referring to FIGS. 1A, 1B, and 1C, it is seen that the area on which components may be mounted extends over the entire height of the board at the top of the board, and is only slightly less at the bottom. The comb of connector contacts at the bottom of the module contains 184 contact fingers, and is designed to mate with a 184-pin edge connector.

Referring now to FIGS. 1A, 1B, and 1C, the back face of the board is essentially the mirror image of the front face, with the exception of the Register chip and PLL chip, which only appear on one side.

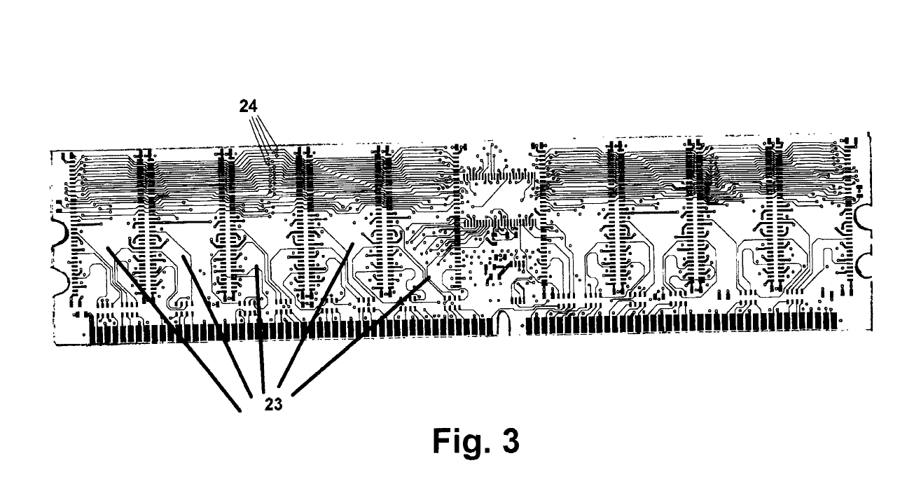

Although not shown in these figures, the DIMM PC board is a multilayer board, typically having six layers. The surface layers, as shown in FIG. 3 (the top layer), contain the connections to the components mounted on the surfaces. Directly beneath the surface layers are the ground plane, beneath one surface, and the Vcc (power) plane on the other surface. And in the center, between the ground and Vcc planes, are the signal printed wires, and the clock printed wires. Communications between layers is done by means of feed-throughs, which are plated-through holes to make good electrical connections between the layers.

In the figures described above, in a line above the SDRAM chips appear a number of decoupling capacitors 4, which have their long axes parallel to the major axis of the DIMM board, further reducing the size of the component area. Each decoupling capacitor is mounted to the DIMM in proximity to the SDRAM pin closest to an end of the SDRAM, and less than or equal to 0.7 mm from the body of the SDRAM.

The board itself is shown in FIG. 3, in the 5-4 configuration. The left group of 5 SDRAMs is mounted on the five SDRAM mounting areas 23 as shown in FIG. 3. Shown in this figure are the bus wires, which electrically attach the same pad number of each SDRAM mounting area in the left group with every other pad of the same number: that is, pad no. “n” of the left-most SDRAM in the group is attached to pad no. “n” of the next-to-left-most SDRAM mounting area in the group, etc. This figure further shows that each printed bus wire in the left group has a feed through 24 located in the middle of the middle SDRAM mounting area. Each feed through connects with a printed wire on the back of the surface layer or on another layer of the multilayer board.

Referring again to FIGS. 1A and 1B, it is noted that the SDRAMs 2 are mounted with their major axis perpendicular to the major axis of the PC board. There are only small margins above and below the SDRAMs. Only the decoupling capacitors 4 appear above the SDRAMs, and these are mounted with their major axis parallel to the major axis of the PC board, so that the amount of space required for their mounting is minimized. A number of small components are mounted below the SDRAMs in FIGS. 1A, 1B, and 1C. The major components are mounted in the gap between the left group of SDRAMs and the right group.

The configuration shown in FIGS. 1A, 1B, and 1C is a departure from the prior art, in which the major components were mounted below the bottom of the SDRAMs, thus requiring additional height of the PC board to accommodate them.

Regardless of the configuration used, whether 5-4, 4-5, or 4-1-4, the principle governing the configuration is the same: first, all, or all but one, of the SDRAMs are mounted in a single row, with a gap in the center, and at least four SDRAMs on each side of the gap; next, the height of the board is substantially the dimension of the major axis of the SDRAM; with all other components of any significant size mounted in the gap; and finally, the components mounted on the margins of the board are oriented with their major axis parallel to the major axis of the module.

### CONFIGURATION OF THE SDRAM MOUNTING PADS

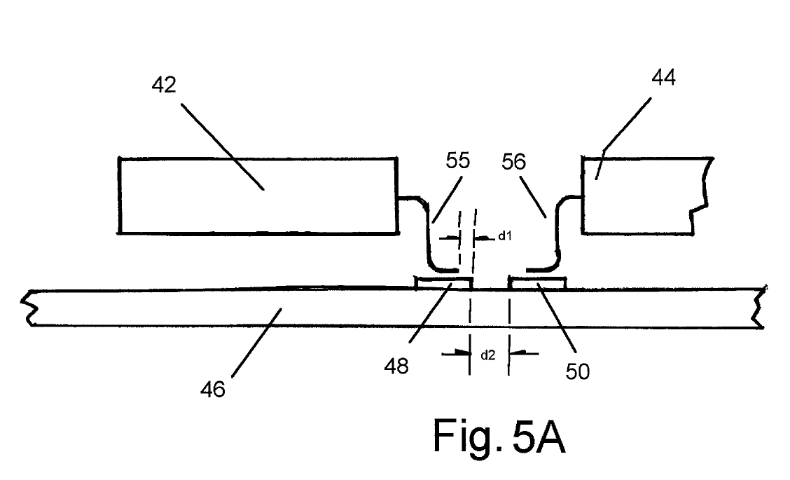

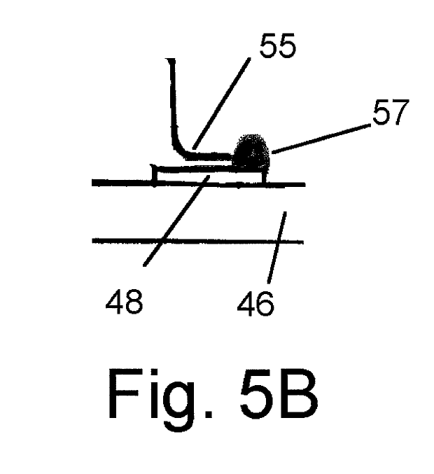

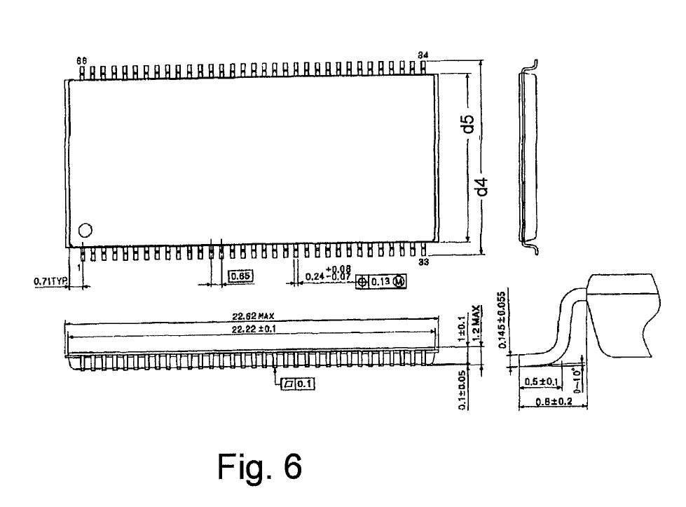

A second major consideration in the configuration of the memory module is the layout of the pads. Referring now to FIG. 5A, a cross-sectional view of two adjacent SDRAMs mounted on the PC board is shown. A left SDRAM 42 is attached to pad 48, affixed to PC board 46, by means of pin 55. A right SDRAM 44 is attached to pad 50, also affixed to the PC board, via pin 56.

In the current invention, the distance from the end of SDRAM pin 55 to the end of the corresponding pad 48, shown as d1 in FIG. 5, is about 0.1 mm, after soldering of the multilayer board has been completed. The space between adjacent pads, shown in FIG. 5 as d2, is between 0.127 mm to 0.750 mm.

The reason for the restriction of the first dimension may be seen by referring to FIG. 5B, showing a close-up view of the left-most pad of FIG. 5A. This view shows the connection between the pin 55 and the pad 48 after soldering. A solder bump 57 is shown in this figure, exaggerated for emphasis. The existence of this bump can prevent stress on the underlying joint exerted by the pin, which would making the joint subject to cracking and other stress failures. If the distance d1 becomes too small, or goes negative, there is the risk of joint failure due to stresses. So the dimension used here for distance d1 must be maintained at a minimum of 0.1 mm.

Also shown in this drawing is dimension d2, the space between adjacent pads. It is necessary to make this space as small as possible, but to still leave enough room between adjacent pads to avoid the danger of shorting. The optimum dimension for this inter-pad distance has been found to be 0.7 mm. Other, smaller dimensions are also acceptable, with the smallest allowable dimension being 0.127 mm.

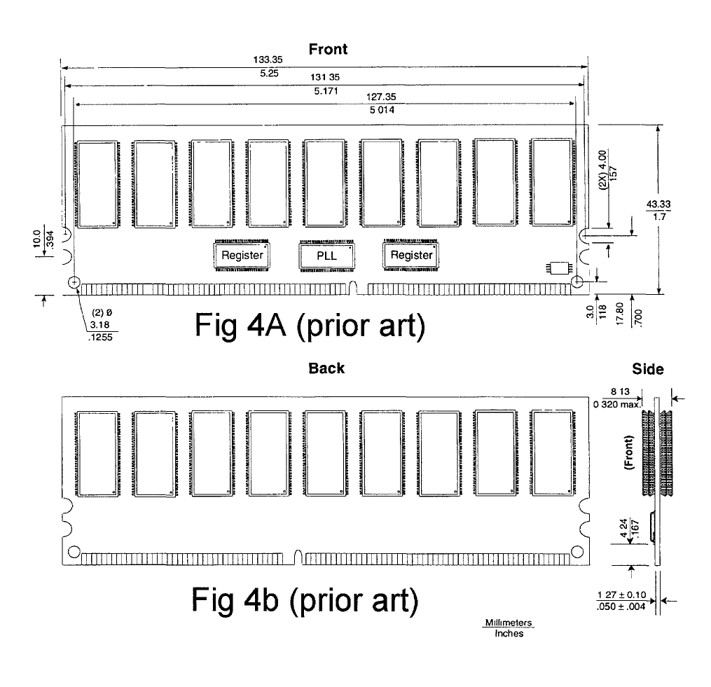

Referring now to FIG. 4B, the length of the “footprint” of the SDRAM, that is, distance between the first and last pad, as measured lengthwise along the SDRAM mounting area, and shown in FIG. 4B as dimension d3, is a minimum of 11.76 mm.

It has been found necessary to incorporate a combination of all the techniques described herein in order to be able to reduce the height of the DIMM module to approximately 1.2 inches. As has been mentioned, however, these techniques may be used separately to advantage in other printed circuit applications.

While the invention has been described with reference to specific embodiments, it will be apparent that improvements and modifications may be made within the purview of the invention without departing from the scope of the invention defined in the appended claims.

I claim:

1. A low-profile DIMM, comprising:
(a) two or more printed circuit boards, bonded together to form a single multilayer board, having two sides, said board having a height of approximately 1.2 inches, and a width of approximately 5.25 inches; and
(b) on each side, a multiplicity of SDRAM chips, each having a major axis; and
(c) a multiplicity of other components, mounted on both sides of said multilayer board,
and wherein, on each side of the multilayer board the SDRAM chips are arranged in a single row, all their major axis perpendicular to the major axis of the multilayer board, said row further comprising a left group and a right group with a space between the groups, and wherein all the other components of significant size are mounted in the space between the left and right groups.

2. The DIMM of claim 1, wherein the left group further comprises 5 SDRAM chips, and wherein the right group further comprises 4 SDRAM chips.

3. The DIMM of claim 1, wherein the left group further comprises 4 SDRAM chips, and wherein the right group further comprises 5 SDRAM chips.

4. The DIMM of claims 1, 2 or 3, wherein each of the SDRAM chips further comprises a plurality of pins, the DIMM further comprising a multiplicity of SDRAM mounting areas, each comprising two rows, each row further comprising a plurality of pads, each pad electrically connected to one of the pins of a corresponding SDRAM chip, each such pad having an extension beyond the corresponding pin of about 0.1 mm after said pins are soldered to said pads.

5. The DIMM of claim 4, wherein the space between adjacent pads is between 0.127 mm and 0.750 mm.

6. The DIMM of claim 1, wherein the space between adjacent pads is between 0.127 mm and 0.750 mm.

7. The DIMM of claim 6, wherein the left group further comprises 5 SDRAM chips, and wherein the right group further comprises 4 SDRAM chips.

8. The DIMM of claim 6, wherein the left group further comprises 4 SDRAM chips, and wherein the right group further comprises 5 SDRAM chips.

9. The DIMM of claims 6, 7 or 8, wherein each of the SDRAM chips further comprises a plurality of pins, the DIMM further comprising a multiplicity of SDRAM mounting areas, each comprising two rows, each row further comprising a plurality of pads, each pad electrically connected to one of the pins of a corresponding SDRAM chip, each such pad having an extension beyond the corresponding pin of about 0.1 mm after said pins are soldered to said pads.

10. The DIMM of claim 9, further comprising a Register chip having a major axis, and wherein the register chip is mounted with its major axis parallel to the major axis of the DIMM.

11. The DIMM of claim 10, further comprising a PLL chip having a major axis, and wherein the PLL chip is mounted with its major axis parallel to the major axis of the DIMM.

12. The DIMM of claims 1, 2, 3, 6, 7 or 8 wherein the additional components further comprise a plurality of decoupling capacitors each having a major axis, and wherein each decoupling capacitor is mounted, with its major axis parallel to the major axis of the DIMM, in proximity to the SDRAM pin closes to an end of said SDRAM, and less than or equal to 0.7 mm from the body of the SDRAM.

13. A low-profile DIMM, comprising:
(a) two or more printed circuit boards, bonded together to form a single multilayer board, having two sides, said board having a height of approximately 1.2 inches, and a width of approximately 5.25 inches; and
(b) on each side, a multiplicity of SDRAM chips, each having a major axis, arranged in a single row, all save one having its major axis perpendicular to the major axis of the multilayer board, said row further comprising a left group comprising 4 SDRAMS, and a right group comprising 4 SDRAMS with a space between the groups, and wherein the remaining SDRAM is mounted in the space between the groups, its major axis perpendicular to the major axis of the DIMM; and
a multiplicity of other components, mounted on both sides of said multilayer board, all the other components of significant size are mounted in the space between the left and right groups.

14. The DIMM of claim 13, wherein each of the SDRAM chips further comprises a plurality of pins, the DIMM further comprising a multiplicity of SDRAM mounting areas, each comprising two rows, each row further comprising a plurality of pads, each pad electrically connected to one of the pins of a corresponding SDRAM chip, each such pad having an extension beyond the corresponding pin of 0.1 mm minimum after said pins are soldered to said pads.

15. The DIMM of claim 13 or 14, wherein the space between adjacent pads is between 0.127 mm and 0.750 mm.

16. The DIMM of claims 15, wherein each of the SDRAM chips further comprises a plurality of pins, the DIMM further comprising a multiplicity of SDRAM mounting areas, each comprising two rows, each row further comprising a plurality of pads, each pad electrically connected to one of the pins of a corresponding SDRAM chip, each such pad having an extension beyond the corresponding pin of about 0.1 mm minimum after said pins are soldered to said pads.

17. The DIMM of claim 13, wherein each of the SDRAM chips further comprises a plurality of pins, the DIMM further comprising a multiplicity of SDRAM mounting areas, each comprising two rows, each row further comprising a plurality of pads, each pad electrically connected to one of the pins of a corresponding SDRAM chip, each such pad having an extension beyond the corresponding pin of about 0.1 mm minimum after said pins are soldered to said pads.

18. The DIMM of claim 16, further comprising a Register chip having a major axis, and wherein the register chip is mounted with its major axis parallel to the major axis of the DIMM.

19. The DIMM of claim 18, further comprising a PLL chip having a major axis, and wherein the PLL chip is mounted with its major axis parallel to the major axis of the DIMM.

20. The DIMM of claims 13, 14 or 17 wherein the additional components further comprise a plurality of decoupling capacitors each having a major axis, and wherein each decoupling capacitor is mounted, with its major axis parallel to the major axis of the DIMM, in proximity to the SDRAM pin closes to an end of said SDRAM, and less than or equal to 0.7 mm from the body of the SDRAM.

21. The DIMM of claim 15 wherein the additional components further comprise a plurality of decoupling capacitors each having a major axis, and wherein each decoupling capacitor is mounted, with its major axis parallel to the major axis of the DIMM, in proximity to the SDRAM pin closes to an end of said SDRAM, and less than or equal to 0.7 mm from the body of the SDRAM.

22. The DIMM of claim 16, wherein the additional components further comprise a plurality of decoupling capacitors each having a major axis, and wherein each decoupling capacitor is mounted, with its major axis parallel to the major axis of the DIMM, in proximity to the SDRAM pin closes to an end of said SDRAM, and less than or equal to 0.7 mm from the body of the SDRAM.
